(19) United States
(12) Patent Application Publication
(10) Pub. No.: US 2021/0026235 A1
(43) Pub. Date: Jan. 28, 2021

(54) MASK BLANK, PHASE SHIFT MASK, AND METHOD FOR MANUFACTURING SEMICONDUCTOR DEVICE

(71) Applicant: HOYA CORPORATION, Tokyo (JP)

(72) Inventors: Hitoshi MAEDA, Tokyo (JP); Osamu NOZAWA, Tokyo (JP); Yasutaka HORIGOME, Tokyo (JP)

(73) Assignee: HOYA CORPORATION, Tokyo (JP)

(21) Appl. No.: 17/040,937

(22) PCT Filed: Mar. 15, 2019
(86) PCT No.: PCT/JP2019/010772

§ 371 Date: Sep. 23, 2020

(30) Foreign Application Priority Data
Mar. 26, 2018 (JP) 2018-058004

(51) Int. Cl. G03F 1/32; G03F 1/72; G03F 1/84; G03F 1/80; H01L 21/033

(52) U.S. Cl. CPC G03F 1/32; G03F 1/72; H01L 21/0337; G03F 1/80; G03F 1/84

(57) ABSTRACT

A mask blank has a phase shift film of a structure in which a lower layer, an intermediate layer, and an upper layer are layered in this order. The lower layer is formed of a silicon-nitride-based material. The intermediate layer is formed of silicon-oxynitride-based material. The upper layer is formed of a silicon-oxide-based material. The nitrogen content of the lower layer is greater than those of the intermediate and the upper layers. The oxygen content of the upper layer is greater than those of the intermediate and the lower layers. The ratio of the film thickness of the intermediate layer with respect to the overall film thickness of the phase shift film is 0.15 or more, and the ratio of the film thickness of the upper layer with respect to the overall film thickness of the phase shift film is 0.10 or more.

### CROSS-REFERENCE TO RELATED APPLICATIONS

This application is a National Stage of International Application No. PCT/JP2019/010772, filed Mar. 15, 2019, which claims priority to Japanese Patent Application No. 2018-058004, filed Mar. 26, 2018, and the contents of which is incorporated by reference.

### TECHNICAL FIELD

This disclosure relates to a mask blank and a phase shift mask manufactured using the mask blank. This disclosure also relates to a method for manufacturing a semiconductor device using the above-mentioned phase shift mask.

### BACKGROUND ART

In a manufacturing process of a semiconductor device, formation of a fine pattern is carried out using photolithography. For the formation of the fine pattern, a number of transfer masks are normally used. In order to miniaturize a pattern of the semiconductor device, it is necessary to shorten a wavelength of an exposure light source used in the photolithography in addition to miniaturization of mask patterns formed on the transfer masks. In recent years, an ArF excimer laser (wavelength of 193 nm) is increasingly used as the exposure light source upon manufacturing the semiconductor device.

As one type of the transfer masks, a halftone phase shift mask is known. The halftone phase shift mask has a light-transmitting portion allowing exposure light to be transmitted therethrough and a phase shift portion (of a halftone phase shift film) allowing the exposure light to be transmitted therethrough in an attenuated state, so that a phase of transmitted exposure light is substantially reversed (with a phase difference of about 180 degrees) between the light-transmitting portion and the phase shift portion. Due to the phase difference, a contrast of an optical image at a boundary between the light-transmitting portion and the phase shift portion is enhanced so that the halftone phase shift mask becomes a high-resolution transfer mask.

The halftone phase shift mask has a tendency that a transferred image has a higher contrast as the halftone phase shift film has a higher transmittance with respect to the exposure light. Therefore, mainly in case where an especially high resolution is required, a so-called high-transmittance halftone phase shift mask is used. For the phase shift film of the halftone phase shift mask, a molybdenum silicide (MoSi) based material is widely used. However, it has recently been found out that an MoSi-based film is low in resistance (so-called ArF lightfastness) against exposure light (hereinafter referred to as ArF exposure light) of the ArF excimer laser. In Patent Document 1, plasma treatment, UV irradiation treatment, or heat treatment is carried out to form a protective film of SiON, SiO₂, or the like on a surface of a pattern of the MoSi-based film so as to improve the ArF lightfastness.

As the phase shift film of the halftone phase shift mask, a SiN-based material comprising silicon and nitrogen is also known and is disclosed in, for example, Patent Document 2. Furthermore, as a technique for obtaining desired optical characteristics, Patent Document 3 discloses a halftone phase shift mask using a phase shift film comprising a periodic multilayer film including Si oxide layers and Si nitride layers. Since the SiN-based material has high ArF lighffastness, attention is focused on a high-transmittance halftone phase shift mask using the SiN-based film as the phase shift film.

### PRIOR ART DOCUMENT(S)

### Patent Document(s)

[Patent Document 1] JP 2010-217514 A

[Patent Document 2] JP H07-134392 A

[Patent Document 3] JP 2002-535702 A

### SUMMARY OF THE DISCLOSURE

### Problem to be Solved by the Disclosure

As compared with the above-mentioned MoSi-based film, both of the silicon nitride layer and the silicon oxide layer are considerably high in ArF lightfastness. However, it has been found out that, in case where the phase shift film of the halftone phase shift mask is formed of a silicon nitride based material and, as ordinary use of the phase shift mask, the phase shift mask is set in an exposure apparatus and repeatedly irradiated with ArF exposure light, relatively large variation is caused in transmittance and phase difference of the phase shift film before and after the use. Variation in transmittance and phase difference of the phase shift film during use of the phase shift mask leads to decrease in transfer accuracy of the phase shift mask. The phase difference is a difference between a phase of the exposure light transmitted through the inside of the phase shift film and a phase of the exposure light transmitted through air for a same distance as a thickness of the phase shift film. The same applies hereinafter.

A thin film of a silicon oxide based material is high in ArF lightfastness as compared with a thin film of a silicon nitride based material. In case where the phase shift film is formed of the silicon oxide based material, variation in phase difference of the phase shift film is small before and after the use as the phase shift mask. However, a single-layer film of the silicon oxide based material has an excessively high transmittance for the ArF exposure light and, therefore, is not suitable as the phase shift film of the halftone phase shift mask. In view of the above, attempt has been made to inhibit the variation in transmittance and phase difference of the phase shift film caused under repeated irradiation with the ArF exposure light by forming the phase shift film with a two-layer structure comprising a lower layer of the silicon nitride based material and an upper layer of the silicon oxide based material. However, the variation in transmittance due to the repeated irradiation with the ArF exposure light could not sufficiently be inhibited.

Generally, a fluorine-based gas is used in dry etching performed when the thin film of the silicon nitride based material is patterned. A glass material containing silicon oxide as a main component is used for a transparent substrate of the phase shift mask. The transparent substrate also has a characteristic of being etched by the fluorine-based gas. When the transparent substrate is etched and excessively eroded by the dry etching upon patterning the thin film of the silicon nitride based material, there arises a problem such as in-plane uniformity of the phase difference. Therefore, in the dry etching upon forming a pattern on the thin film of the silicon nitride based material, a fluorine-based gas, such as SF₆, is used because predetermined or higher etching selectivity is obtained with respect to the transparent substrate. However, it has been found out that, in case where the pattern is formed by dry etching using SF₆ on the phase shift film having the two-layer structure including the lower layer of the silicon nitride based material and the upper layer of the silicon oxide based material as mentioned above, a relatively large step is produced between the upper layer and the lower layer at a sidewall of the pattern formed on the phase shift film. This is because an etching rate of the upper layer of the silicon oxide based material which is similar to the material of the transparent substrate is considerably slower than an etching rate of the lower layer of the silicon nitride based material. If a large step is present at the sidewall of the pattern of the phase shift film, decrease in transfer accuracy is caused to occur.

On the other hand, as a mask defect repair technique for the halftone phase shift mask, use is sometimes made of a defect repair technique of etching and removing a black defect portion of the phase shift film by supplying a xenon difluoride (XeF₂) gas to the black defect portion and irradiating that portion with an electron beam to change the black defect portion into volatile fluoride. Hereinafter, the above-mentioned defect repair by irradiation with charged particles such as the electron beam will simply be called EB (Electron Beam) defect repair. In case where the EB defect repair is performed on the above-mentioned phase shift film of the two-layer structure after the pattern is formed thereon, a repair rate of the lower layer of the silicon nitride based material tends to be faster than a repair rate of the upper layer of the silicon oxide based material. In addition, in case of the EB defect repair, etching is performed on the pattern of the phase shift film in a state where the sidewall is exposed and, accordingly, side etching which advances in a sidewall direction of the pattern easily enters into, in particular, a nitrogen-containing layer. Therefore, the sidewall of the pattern of the phase shift film after the EB defect repair tends to have a stepped shape with the step formed between the lower layer and the upper layer. A large step present at the sidewall of the pattern of the phase shift film results in decrease in transfer accuracy.

In order to solve the above-mentioned problem, this disclosure has been made. It is an aspect of this disclosure to provide a mask blank which comprises a transparent substrate and a phase shift film formed thereon and including a lower layer of a silicon nitride based material and an upper layer of a silicon oxide based material and which is capable of inhibiting variation in transmittance and phase difference of the phase shift film that is caused under repeated irradiation with ArF exposure light.

It is another aspect of this disclosure to provide a mask blank which comprises a transparent substrate and a phase shift film formed thereon and including a lower layer of a silicon nitride based material and an upper layer of a silicon oxide based material and which is capable of reducing, when the phase shift film is dry etched by a fluorine-based gas to form a pattern, a step produced at a sidewall of the pattern of the phase shift film.

It is a further aspect of this disclosure to provide a mask blank which comprises a transparent substrate and a phase shift film formed thereon and including a lower layer of a silicon nitride based material and an upper layer of a silicon oxide based material and which is capable of reducing, when EB defect repair is performed on a pattern of a phase shift film of a phase shift mask manufactured from the mask blank, a step produced at a sidewall of the pattern of the phase shift film after the EB defect repair.

It is still another aspect of this disclosure to provide a phase shift mask manufactured using the mask blank. It is yet another aspect of this disclosure to provide a method for manufacturing a semiconductor device using the phase shift mask.

### Means to Solve the Problem

In order to solve the above-mentioned problem, this disclosure has following configurations.

### Configuration 1

A mask blank comprising a transparent substrate and a phase shift film formed thereon, wherein the phase shift film has a structure in which a lower layer, an intermediate layer, and an upper layer are formed in this order from the transparent substrate, wherein the lower layer is formed of a material consisting of silicon and nitrogen or a material consisting of silicon, nitrogen, and one or more elements selected from metalloid elements and non-metal elements, wherein the intermediate layer is formed of a material consisting of silicon, nitrogen, and oxygen or a material consisting of silicon, nitrogen, oxygen, and one or more elements selected from metalloid elements and non-metal elements, wherein the upper layer is formed of a material consisting of silicon and oxygen or a material consisting of silicon, oxygen, and one or more elements selected from metalloid elements and non-metal elements, wherein the lower layer is greater in nitrogen content than the intermediate layer and the upper layer, wherein the upper layer is greater in oxygen content than the intermediate layer and the lower layer, wherein a ratio of film thickness of the intermediate layer is 0.15 or more with respect to an overall film thickness of the phase shift film, and wherein a ratio of film thickness of the upper layer is 0.10 or less with respect to the overall film thickness of the phase shift film.

### Configuration 2

The mask blank according to Configuration 1, wherein a ratio of film thickness of the lower layer is 0.80 or less with respect to the overall film thickness of the phase shift film.

### Configuration 3

The mask blank according to Configuration 1 or 2, wherein the intermediate layer is greater in nitrogen content than the upper layer and greater in oxygen content than the lower layer.

### Configuration 4

The mask blank according to any one of Configurations 1 to 3, wherein the intermediate layer has a nitrogen content of 30 atomic % or more and an oxygen content of 10 atomic % or more.

### Configuration 5

The mask blank according to any one of Configurations 1 to 4, wherein the lower layer has a nitrogen content of 50 atomic % or more.

### Configuration 6

The mask blank according to any one of Configurations 1 to 5, wherein the upper layer has an oxygen content of 50 atomic % or more.

### Configuration 7

The mask blank according to any one of Configurations 1 to 6, wherein the lower layer is greater in film thickness than the intermediate layer and the upper layer and the intermediate layer is greater in film thickness than the upper layer.

### Configuration 8

The mask blank according to any one of Configurations 1 to 7, wherein the phase shift film has a function of allowing exposure light of an ArF excimer laser to be transmitted therethrough at a transmittance of 2% or more and a function of causing a phase difference of 150 degrees or more and 200 degrees or less between the exposure light transmitted through the phase shift film and the exposure light transmitted through air for a same distance as a thickness of the phase shift film.

### Configuration 9

The mask blank according to any one of Configurations 1 to 8, comprising a light shielding film formed on the phase shift film.

### Configuration 10

A phase shift mask comprising a transparent substrate and a phase shift film formed thereon and having a transparent pattern, wherein the phase shift film has a structure in which a lower layer, an intermediate layer, and an upper layer are formed in this order from the transparent substrate, wherein the lower layer is formed of a material consisting of silicon and nitrogen or a material consisting of silicon, nitrogen, and one or more elements selected from metalloid elements and non-metal elements, wherein the intermediate layer is formed of a material consisting of silicon, nitrogen, and oxygen or a material consisting of silicon, nitrogen, oxygen, and one or more elements selected from metalloid elements and non-metal elements, wherein the upper layer is formed of a material consisting of silicon and oxygen or a material consisting of silicon, oxygen, and one or more elements selected from metalloid elements and non-metal elements, wherein the lower layer is greater in nitrogen content than the intermediate layer and the upper layer, wherein the upper layer is greater in oxygen content than the intermediate layer and the lower layer, wherein a ratio of film thickness of the intermediate layer is 0.15 or more with respect to an overall film thickness of the phase shift film, and wherein a ratio of film thickness of the upper layer is 0.10 or less with respect to the overall film thickness of the phase shift film.

### Configuration 11

The phase shift mask according to Configuration 10, wherein a ratio of film thickness of the lower layer is 0.80 or less with respect to the overall film thickness of the phase shift film.

### Configuration 12

The phase shift mask according to Configuration 10 or 11, wherein the intermediate layer is greater in nitrogen content than the upper layer and greater in oxygen content than the lower layer.

### Configuration 13

The phase shift mask according to any one of Configurations 10 to 12, wherein the intermediate layer has a nitrogen content of 30 atomic % or more and an oxygen content of 10 atomic % or more.

### Configuration 14

The phase shift mask according to any one of Configurations 10 to 13, wherein the lower layer has a nitrogen content of 50 atomic % or more.

### Configuration 15

The phase shift mask according to any one of Configurations 10 to 14, wherein the upper layer has an oxygen content of 50 atomic % or more.

### Configuration 16

The phase shift mask according to any one of Configurations 10 to 15, wherein the lower layer is greater in film thickness that the intermediate layer and the upper layer and the intermediate layer is greater in film thickness than the upper layer.

### Configuration 17

The phase shift mask according to any one of Configurations 10 to 16, wherein the phase shift film has a function of allowing exposure light of an ArF excimer laser to be transmitted therethrough at a transmittance of 2% or more and a function of causing a phase difference of 150 degrees or more and 200 degrees or less between the exposure light transmitted through the phase shift film and the exposure light transmitted through air for a same distance as a thickness of the phase shift film.

### Configuration 18

The phase shift mask according to any one of Configurations 10 to 17, further comprising a light shielding film formed on the phase shift film and having a light shielding pattern.

### Configuration 19

A method for manufacturing a semiconductor device, comprising a step of carrying out exposure transfer of a transfer pattern onto a resist film on a semiconductor substrate by using the phase shift mask according to any one of Configurations 10 to 18.

### Effect of the Invention

A mask blank according to this disclosure comprises a transparent substrate and a phase shift film formed thereon and is characterized in that the phase shift film has a structure in which a lower layer, an intermediate layer, and an upper layer are formed in this order from the transparent substrate, that the lower layer is formed of a material consisting of silicon and nitrogen or a material consisting of silicon, nitrogen, and one or more elements selected from metalloid elements and non-metal elements, that the intermediate layer is formed of a material consisting of silicon, nitrogen, and oxygen or a material consisting of silicon, nitrogen, oxygen, and one or more elements selected from metalloid elements and non-metal elements, that the upper layer is formed of a material consisting of silicon and oxygen or a material consisting of silicon, oxygen, and one or more elements selected from metalloid elements and non-metal elements, that the lower layer is greater in nitrogen content than the intermediate layer and the upper layer, the upper layer is greater in oxygen content than the intermediate layer and the lower layer, that a ratio of film thickness of the intermediate layer is 0.15 or more with respect to an overall film thickness of the phase shift film, and that a ratio of film thickness of the upper layer is 0.10 or less with respect to the overall film thickness of the phase shift film.

With the mask blank having the above-mentioned configuration, it is possible to inhibit variation in transmittance and phase difference of the phase shift film that is caused under repeated irradiation with ArF exposure light. Furthermore, it is possible to reduce, when the phase shift film is dry etched by a fluorine-based gas to form a pattern, a step produced at a sidewall of the pattern of the phase shift film. Moreover, it is possible to reduce, when the pattern of the phase shift film of the phase shift mask manufactured from the mask blank is subjected to EB defect repair, a step produced at a sidewall of the pattern of the phase shift film after the EB defect repair.

The phase shift mask according to this disclosure is characterized in that the phase shift film having the transfer pattern is similar in configuration to the phase shift film of the above-mentioned mask blank according to this disclosure. With the phase shift mask, it is possible to inhibit variation in transmittance and phase difference of the phase shift film that is caused under repeated irradiation with ArF exposure light. Furthermore, it is possible to reduce a step produced at a sidewall of the pattern of the phase shift film. Moreover, it is possible to reduce, when the pattern of the phase shift film of the phase shift mask is subjected to EB defect repair, a step produced at the sidewall of the pattern of the phase shift film after the EB defect repair. The phase shift mask of this disclosure is high in transfer accuracy when exposure transfer is performed on a transfer object such as a resist film on a semiconductor substrate.

### BRIEF DESCRIPTION OF THE DRAWINGS

FIG. 1 is a sectional view for illustrating a configuration of a mask blank according to an embodiment of this disclosure; and

FIGS. 2A, 2B, 2C, 2D, 2E, and 2F are sectional views for illustrating a manufacturing process of a phase shift mask in the embodiment of this disclosure.

### MODE FOR EMBODYING THE INVENTION

At first, a process leading to completion of this disclosure will be described. With respect to a case where a phase shift film of a mask blank has a structure including a lower layer of a silicon nitride based material and an upper layer of a silicon oxide based material, the present inventors conducted researches in view of variation in transmittance and phase difference of the phase shift film that is caused under repeated irradiation with ArF exposure light, in view of a step produced at a sidewall of a pattern of the phase shift film when the phase shift film is dry etched by a fluorine-based gas to form the pattern, and in view of a step produced when EB defect repair is performed on a pattern of a phase shift film of a phase shift mask.

In case of a phase shift film of a MoSi-based material, as a countermeasure against the following problems, a silicon oxide layer is formed as a surface layer so as to improve ArF lightfastness. Specifically, in case of the phase shift film of the MoSi-based material, a phenomenon occurs that molybdenum excited under irradiation with the ArF exposure light is bonded with oxygen in air to be released from the phase shift film. Thus, molybdenum is released. This causes a state where oxygen in air easily intrudes into the phase shift film. In addition, there arises a phenomenon that silicon in the phase shift film is also excited and bonded with oxygen in air to cause volume expansion of the phase shift film (phenomenon of so-called thickening of the pattern of the phase shift film). These phenomena have become problems. Furthermore, molybdenum which functions towards a decrease in transmittance with respect to the ArF exposure light is released from the phase shift film whereas oxygen which functions towards an increase in transmittance with respect to the ArF exposure light is bonded with silicon in the phase shift film. This causes a problem that the transmittance of the phase shift film with respect to the ArF exposure light is significantly increased from that at the time of film formation. Furthermore, there arises a problem that the phase difference of the phase shift film with respect to the ArF exposure light is considerably varied from that at the time of film formation. Against the above-mentioned problems, the silicon oxide layer is preliminarily formed as the surface layer of the phase shift film as described above so as to inhibit molybdenum excited under irradiation with the ArF exposure light from being released from the phase shift film and to prevent oxygen from intruding into the phase shift film. In addition, it is possible to reduce both the phenomenon of thickening of the pattern and the phenomenon of significant variation in transmittance and phase difference.

As compared with the phase shift film of the MoSi-based material, the phase shift film of the silicon nitride based material is considerably small in thickening of the pattern of the phase shift film under the repeated irradiation with the ArF exposure light even if the silicon oxide layer is not formed as the surface layer. The phase shift film of the silicon nitride based material is also small in variation width of the transmittance and the phase difference of the phase shift film under the repeated irradiation with the ArF exposure light. In case of a phase shift mask used in exposure transfer of a very fine pattern, an allowable width of variation from a designed value of each of the transmittance and the phase difference of the phase shift film is very small. In case of a phase shift film comprising a single layer of a silicon nitride based material, the variation width of each of the transmittance and the phase difference before and after the repeated irradiation with the ArF exposure light exceeds the above-mentioned allowable width. In view of the above, it has been attempted to solve the problems by forming the phase shift film of a two-layer structure comprising the lower layer of the silicon nitride based material and the upper layer of the silicon oxide based material, which are formed in this order from the transparent substrate. As a result, in the above-mentioned phase shift film of the two-layer structure, the variation width of the phase difference could be reduced to the above-mentioned allowable width or less. However, the variation width of the transmittance in the above-mentioned phase shift film of the two-layer structure was small as compared with the phase shift film of the single-layer structure of the silicon nitride based material but exceeded the above-mentioned allowable width.

On the other hand, by forming the phase shift film of the two-layer structure including the lower layer of the silicon nitride based material and the upper layer of the silicon oxide based material, two problems newly arise. One of the problems is that, when the phase shift film is patterned by dry etching using the fluorine-based gas, a step is produced at the sidewall of the phase shift film because the lower layer is greater in side etching amount than the upper layer. Another problem is that, in case where the phase shift mask is manufactured by forming the pattern on the phase shift film, thereafter a black defect is found in the pattern of the phase shift film in mask defect inspection, and the black defect is repaired by EB defect repair, a step is formed in a pattern shape after the EB defect repair because the lower layer is faster in repair rate than the upper layer.

The reason why the transmittance of the phase shift film as a whole is varied although the upper layer of the silicon oxide based material is formed is that an internal structure of the silicon nitride based material as the lower layer is low in stability as compared with the silicon oxide based material. In view of the above, it has been considered to change the material of the lower layer into a silicon oxynitride based material. This is because Si—O bonds have high stability as compared with Si—N bonds. However, as compared with the layer of the silicon nitride based material, the layer of the silicon oxynitride based material is small in refractive index n at a wavelength (wavelength of 193 nm) of the ArF exposure light (hereinafter simply referred to as refractive index n), which is an optical constant significantly affecting the phase difference, and is also small in extinction coefficient k at the wavelength (wavelength of 193 nm) of the ArF exposure light (hereinafter simply referred to as extinction coefficient k), which is an optical constant significantly affecting the transmittance. The silicon oxide based material as the upper layer is considerably small in both refractive index n and extinction coefficient k as compared with the silicon oxynitride based material.

Generally, as the refractive index n of the phase shift film is greater, a film thickness required to cause a predetermined phase difference for the ArF exposure light transmitted through the inside of the phase shift film is smaller. As the extinction coefficient k of the phase shift film is greater, a film thickness required to transmit the ArF exposure light transmitted through the inside of the phase shift film at a predetermined transmittance is smaller. Accordingly, in case of the phase shift film having the layered structure including the lower layer of the silicon oxynitride based material and the upper layer of the silicon oxide based material, there is a problem that an overall film thickness of the phase shift film required to satisfy optical characteristics of the predetermined transmittance and the predetermined phase difference is increased as compared with the phase shift film having the layered structure including the lower layer of the silicon nitride based material and the upper layer of the silicon oxide based material. In relation thereto, there is a problem that the degree of freedom in designing the phase shift film is lowered. Furthermore, there is a problem that, in case where the phase shift film is formed in contact with a surface of the transparent substrate, the lower layer of the silicon oxynitride based material is low in etching selectivity for dry etching by the fluorine-based gas with respect to the transparent substrate as compared with the lower layer of the silicon nitride based material.

In order to solve the above-mentioned problems, it has been considered to form the phase shift film with a layered structure including a lower layer of a silicon nitride based material, an intermediate layer of a silicon oxynitride based material, and an upper layer of a silicon oxide based material.

By forming the upper layer of the silicon oxide based material, it is possible to inhibit intrusion of oxygen from a surface of the phase shift film into the inside thereof under the repeated irradiation with the ArF exposure light. On the other hand, formation of the upper layer of the silicon oxide based material becomes a factor of causing a step to be produced at a pattern sidewall of the phase shift film after dry etching, a factor of causing a step to be produced at the pattern sidewall of the phase shift film after EB defect repair, and a factor of increasing the overall film thickness of the phase shift film. If the upper layer of the silicon oxide based material can protect an entire surface of the intermediate layer, an effect of inhibiting intrusion of oxygen into the inside of the phase shift film is obtained. Then, the thickness of the upper layer may be small. In view of the above, the ratio of the film thickness of the upper layer of the silicon oxide based material is determined to be 0.1 or less with respect to the overall film thickness of the phase shift film.

For the intermediate layer, the silicon oxynitride based material is used which is hardly changed in optical characteristics under the repeated irradiation with the ArF exposure light, as compared with the silicon nitride based material. The intermediate layer is formed to inhibit the variation in transmittance of the phase shift film as a whole with respect to the exposure light. In view of obtaining the above-mentioned effect, the ratio of the film thickness of the intermediate layer of the silicon oxynitride based material is determined to be 0.15 or more with respect to the overall film thickness of the phase shift film. The intermediate layer has an intermediate characteristic that the etching rate for dry etching by the fluorine-based gas is slower than that of the lower layer and faster than that of the upper layer. Therefore, after the phase shift film of the three-layer structure is patterned, the side etching amount of the pattern sidewall is intermediate between those of the lower layer and the upper layer, and change in profile (for example, step) of the pattern sidewall in a film thickness direction can be reduced. The intermediate layer has an intermediate characteristic that the repair rate in the EB defect repair is slower than that of the lower layer and faster than that of the upper layer. Therefore, it is possible to reduce the change in profile (for example, step) of the pattern sidewall in the film thickness direction after the EB defect repair is performed on the pattern of the phase shift film having the three-layer structure.

As a result of the diligent researches mentioned above, the mask blank of this disclosure has been derived. Specifically, a mask blank according to this disclosure comprises a transparent substrate and a phase shift film formed thereon and is characterized in that the phase shift film has a structure in which a lower layer, an intermediate layer, and an upper layer are formed in this order from the transparent substrate, that the lower layer is formed of a material consisting of silicon and nitrogen or a material consisting of silicon, nitrogen, and one or more elements selected from metalloid elements and non-metal elements, that the intermediate layer is formed of a material consisting of silicon, nitrogen, and oxygen or a material consisting of silicon, nitrogen, oxygen, and one or more elements selected from metalloid elements and non-metal elements, that the upper layer is formed of a material consisting of silicon and oxygen or a material consisting of silicon, oxygen, and one or more elements selected from metalloid elements and non-metal elements, that the lower layer is greater in nitrogen content than the intermediate layer and the upper layer, the upper layer is greater in oxygen content than the intermediate layer and the lower layer; that a ratio of film thickness of the intermediate layer is 0.15 or more with respect to an overall film thickness of the phase shift film, and that a ratio of film thickness of the upper layer is 0.10 or less with respect to the overall film thickness of the phase shift film.

Next, an embodiment of this disclosure will be described. A mask blank according to this disclosure is applicable to a mask blank for use in producing a phase shift mask. Hereinafter, description will be made of a mask blank for use in manufacturing a halftone phase shift mask.

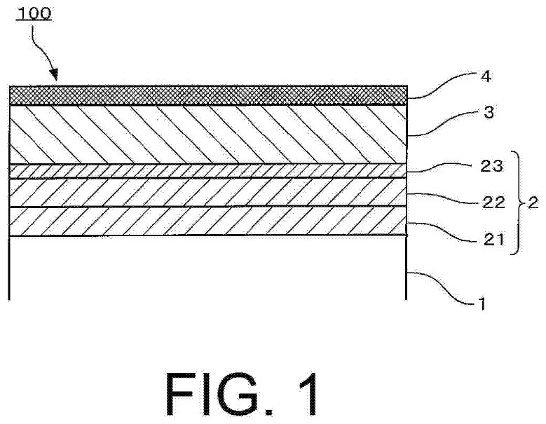

FIG. 1 is a sectional view for illustrating a configuration of a mask blank 100 according to the embodiment of this disclosure. The mask blank 100 illustrated in FIG. 1 has a structure in which a phase shift film 2, a light shielding film 3, and a hard mask film 4 are formed as layers on a transparent substrate 1 in this order.

The transparent substrate 1 may be formed of a glass material such as synthesized quartz glass, quartz glass, aluminosilicate glass, soda lime glass, and low-thermal-expansion glass (SiO₂—TiO₂ glass or the like). Among others, the synthetic quartz glass is particularly preferable as a material for use in forming the transparent substrate 1 of the mask blank 100 because of a high transmittance with respect to ArF excimer laser light (wavelength of 193 nm).

The phase shift film 2 is required to have a transmittance allowing a phase shift effect to effectively function. The phase shift film 2 preferably has a transmittance of 2% or more with respect to ArF exposure light. The phase shift film 2 more preferably has a transmittance of 10% or more, further preferably 15% or more with respect to the ArF exposure light. The phase shift film 2 is preferably adjusted to have a transmittance of 40% or less, more preferably 30% or less, with respect to the ArF exposure light.

In recent years, NTD (Negative Tone Development) has become used as an exposure and development process for a resist film on a semiconductor substrate (wafer). In this process, a bright field mask (transfer mask having a high pattern aperture) is frequently used. In a bright-field phase shift mask, a balance between zeroth-order light and first-order light of light transmitted through a light-transmitting portion is improved by making the phase shift film have a transmittance of 10% or more with respect to exposure light. When the above-mentioned balance is improved, an effect of attenuating a light intensity due to an interference by the exposure light transmitted through the phase shift film against the zeroth-order light is further increased so that pattern resolution on the resist film is improved. Accordingly, the transmittance of the phase shift film 2 with respect to the ArF exposure light is preferably 10% or more. In case where the transmittance with respect to the ArF exposure light is 15% or more, a pattern edge enhancement effect of a transfer image (projected optical image) by a phase shift effect is further improved. On the other hand, the transmittance of the phase shift film 2 exceeding 40% with respect to the ArF exposure light is not preferable because the effect of a side lobe becomes excessively strong.

In order to obtain an appropriate phase shift effect, the phase shift film 2 is required to have a function of producing a predetermined phase difference between the ArF exposure light transmitted therethrough and light transmitted through air fora same distance as the thickness of the phase shift film 2. The phase difference is preferably adjusted to fall within a range of 150 degrees or more and 200 degrees or less. The lower limit of the phase difference in the phase shift film 2 is preferably 160 degrees or more, more preferably 170 degrees or more. On the other hand, the upper limit of the phase difference in the phase shift film 2 is more preferably 190 degrees or less.

The phase shift film 2 preferably has a thickness of 90 nm or less, more preferably 80 nm or less. On the other hand, the phase shift film 2 preferably has a thickness of 40 nm or more. If the thickness of the phase shift film 2 is smaller than 40 nm, a predetermined transmittance and a predetermined phase difference required as the phase shift film might not be obtained.

The phase shift film 2 has a structure in which a lower layer 21 of a silicon nitride based material, an intermediate layer 22 of a silicon oxynitride based material, and an upper layer 23 of a silicon oxide material are formed in this order from the transparent substrate 1. The phase shift film 2 may have other layer or layers than the lower layer 21, the intermediate layer 22, and the upper layer 23 as far as the effect of this disclosure is obtained.

The lower layer 21 is preferably formed of a material consisting of silicon and nitrogen, or a material consisting of silicon, nitrogen, and one or more elements selected from metalloid elements and non-metal elements. The lower layer 21 may contain any metalloid element(s) in addition to silicon. Among the metalloid elements, one or more elements selected from boron, germanium, antimony, and tellurium are preferably contained because an increase in conductivity of silicon used as a sputtering target is expected.

The lower layer 21 may contain any non-metal element(s) in addition to nitrogen. The non-metal elements in this case include narrow-sense non-metal elements (nitrogen, carbon, oxygen, phosphorus, sulfur, and selenium), halogens, and noble gases. Among the non-metal elements, one or more elements selected from carbon, fluorine, and hydrogen are preferably contained. The lower layer 21 preferably has an oxygen content of less than 10 atomic %, more preferably 5 atomic % or less, further preferably do not positively contain oxygen (not higher than a detection lower limit when composition analysis is carried out by X-ray photoelectron spectroscopy or the like). If the oxygen content of the lower layer 21 is large, a difference in optical characteristics between the intermediate layer 22 and the upper layer 23 becomes small and the degree of freedom in designing the phase shift film 2 is reduced. In addition, the etching selectivity between the lower layer 21 and the transparent substrate 1 is decreased for dry etching using the fluorine-based gas.

The lower layer 21 may contain a noble gas. The noble gas is an element which is capable of increasing a film-forming rate and improving productivity by presence in a film-forming chamber upon forming the lower layer 21 by reactive sputtering. The noble gas is converted into plasma to collide with a target so that target constituent elements are ejected from the target and, while introducing a reactive gas in the middle, the lower layer 21 is formed on the transparent substrate 1. During a period after the target constituent elements are ejected from the target and before they are adhered to the transparent substrate 1, the noble gas in the film-forming chamber is slightly introduced. Preferable substances as the noble gas required in the reactive sputtering may be argon, krypton, and xenon. In order to relax stress in the lower layer 21, helium and neon, which are small in atomic weight, may positively be introduced into the lower layer 21.

A silicon-based film has a very small refractive index n and a large extinction coefficient k. As the nitrogen content in the silicon-based film is increased, the refractive index n tends to become greater and the extinction coefficient k tends to become smaller. In order to secure a predetermined transmittance required to the phase shift film 2 and simultaneously secure a phase difference with a smaller thickness, the lower layer 21 is preferably formed of a material largest in refractive index n and great in extinction coefficient k. Therefore, the lower layer 21 preferably has a nitrogen content greater than those of the intermediate layer 22 and the upper layer 23.

From the above-mentioned reason, the lower layer 21 preferably has a nitrogen content of 50 atomic % or more, more preferably 51 atomic % or more, further preferably 52 atomic % or more. The lower layer 21 preferably has a nitrogen content of 57 atomic % or less, more preferably 56 atomic % or less. If the lower layer 21 contains nitrogen at a mixing ratio greater than that in Si₃N₄, it is difficult to form the lower layer 21 into an amorphous or a microcrystalline structure. In addition, surface roughness of the lower layer 21 is seriously degraded.

The lower layer 21 preferably has a silicon content of 35 atomic % or more, more preferably 40 atomic % or more, further preferably 45 atomic % or more. The lower layer 21 is preferably formed of a material consisting of silicon and nitrogen. In this case, it may be recognized that the material consisting of silicon and nitrogen encompasses a material containing a noble gas. In the lower layer 21, the total content of silicon and nitrogen is preferably 95 atomic % or more, more preferably 96 atomic % or more, further preferably 98 atomic % or more.

The ratio of the film thickness of the lower layer 21 with respect to the overall film thickness of the phase shift film 2 is preferably 0.80 or less, more preferably 0.70 or less, further preferably 0.60 or less. In case where the ratio of the film thickness of the lower layer 21 is greater than 0.80, the ratio of the film thickness of the intermediate layer 22 is considerably reduced in order to satisfy the conditions of the predetermined transmittance and the predetermined phase difference required to the phase shift film 2 as a whole. If the ratio of the film thickness of the intermediate layer 22 is considerably reduced, the ratio of a region of the phase shift film 2, where optical characteristics hardly change when the phase shift film 2 is subjected to the repeated irradiation with the ArF exposure light, becomes small with respect to an entire region of the phase shift film 2 so that the variation in transmittance and phase difference of the phase shift film 2 is difficult to be inhibited. In addition, in case where the phase shift film 2 is patterned by dry etching using the fluorine-based gas and in case where a black defect is repaired by EB defect repair, the ratio of a region of the intermediate layer 22, where a side etching amount is intermediate between those of the lower layer 21 and the upper layer 23, becomes small with respect to the entire region of the phase shift film 2 so that an effect imposed on transfer accuracy of the phase shift mask at the time of exposure transfer is increased.

On the other hand, the ratio of the film thickness of the lower layer 21 with respect to the overall film thickness of the phase shift film 2 is preferably 0.10 or more, more preferably 0.20 or more, further preferably 0.30 or more. The lower layer 21 is larger in refractive index n and greater in extinction coefficient k than the intermediate layer 22 and the upper layer 23 Therefore, in case where the degree of freedom in designing the phase shift film 2 is increased, it is preferable to secure a predetermined or greater ratio of the film thickness.

The intermediate layer 22 is preferably formed of a material consisting of silicon, nitrogen, and oxygen, or a material consisting of silicon, nitrogen, oxygen, and one or more elements selected from metalloid elements and non-metal elements. The intermediate layer 22 may contain any metalloid elements in addition to silicon. Among the metalloid elements, one or more elements selected from boron, germanium, antimony, and tellurium are preferably contained because an increase in conductivity of silicon used as a sputtering target is expected.

The intermediate layer 22 may contain any non-metal elements in addition to nitrogen and oxygen. The non-metal elements in this case include narrow-sense non-metal elements (nitrogen, carbon, oxygen, phosphorus, sulfur, and selenium), halogens, and noble gases. Among the non-metal elements, one or more elements selected from carbon, fluorine, and hydrogen are preferably contained. The intermediate layer 22 may contain a noble gas, like the lower layer 21.

As compared with the lower layer 21, the intermediate layer 22 is required to be hardly changed in optical characteristics under the repeated irradiation with the ArF exposure light. The intermediate layer 22 is also required to have an intermediate characteristic that the etching rate for dry etching using the fluorine-based gas is slower than that of the lower layer 21 and faster than that of the upper layer 23. Furthermore, the intermediate layer 22 is required to have an intermediate characteristic that the repair rate at the time of EB defect repair is slower than that of the lower layer 21 and faster than that of the upper layer 23. In order to secure a predetermined transmittance required to the phase shift film 2 and simultaneously secure a phase difference with a smaller thickness, the intermediate layer 22 is preferably formed of a material larger in refractive index n and greater in extinction coefficient k than the upper layer 23. Therefore, the intermediate layer 22 preferably has a nitrogen content greater than that of the upper layer 23 and an oxygen content greater than that of the lower layer 21.

From the above-mentioned reason, the intermediate layer 22 preferably has a nitrogen content of 30 atomic % or more, more preferably 35 atomic % or more, further preferably 40 atomic % or more. The intermediate layer 22 preferably has a nitrogen content of less than 50 atomic %, more preferably 45 atomic % or less. On the other hand, the intermediate layer 22 preferably has an oxygen content of 10 atomic % or more, more preferably 15 atomic % or more. The intermediate layer 22 preferably has an oxygen content of 30 atomic % or less, more preferably 25 atomic % or less.

The intermediate layer 22 preferably has a silicon content of 35 atomic % or more, more preferably 40 atomic % or more, further preferably 45 atomic % or more. The intermediate layer 22 is preferably formed of a material consisting of silicon, nitrogen, and oxygen. In this case, it is recognized that the material consisting of silicon, nitrogen, and oxygen encompasses a material containing a noble gas. In the intermediate layer 22, the total content of silicon, nitrogen, and oxygen is preferably 95 atomic % or more, more preferably 96 atomic % or more, further preferably 98 atomic % or more. In the intermediate layer 22, the ratio of the nitrogen content [atomic %] divided by the oxygen content [atomic %] is preferably 1.0 or more, more preferably 1.1 or more, further preferably 1.2 or more. In the intermediate layer 22, the ratio of the nitrogen content [atomic %] divided by the oxygen content [atomic %] is preferably less than 5.0, more preferably 4.8 or less, further preferably 4.5 or less, yet preferably 4.0 or less.

The ratio of the film thickness of the intermediate layer 22 with respect to the overall film thickness of the phase shift film 2 is preferably 0.15 or more, more preferably 0.20 or more, further preferably 0.30 or more. If the above-mentioned ratio of the film thickness of the intermediate layer 22 is smaller than 0.15, the ratio of a region of the phase shift film 2, where optical characteristics hardly change when the phase shift film 2 is subjected to repeated irradiation with the ArF exposure light, becomes small with respect to the entire region of the phase shift film 2 so that the variation in transmittance and phase difference of the phase shift film 2 is difficult to be inhibited. In addition, in case where the phase shift film 2 is patterned by dry etching using the fluorine-based gas and in case where a black defect is repaired by EB defect repair, the ratio of a region of the intermediate layer 22, where a side etching amount is intermediate between those of the lower layer 21 and the upper layer 23, becomes small with respect to the entire region of the phase shift film 2 so that an effect imposed on transfer accuracy of the phase shift mask at the time of exposure transfer is increased.

On the other hand, the ratio of the film thickness of the intermediate layer 22 with respect to the overall film thickness of the phase shift film 2 is preferably 0.80 or less, more preferably 0.70 or less, further preferably 0.6 or less. In case where the above-mentioned ratio of the film thickness of the intermediate layer 22 is greater than 0.80, the ratio of the film thickness of the lower layer 21 is considerably reduced in order to satisfy the conditions of the predetermined transmittance and the predetermined phase difference required to the phase shift film 2 as a whole. The lower layer 21 is larger in refractive index n and greater in extinction coefficient k than the intermediate layer 22 and the upper layer 23. Therefore, in case where the degree of freedom of designing the phase shift film 2 is increased, it is preferable to secure a predetermined or greater ratio of the film thickness.

The upper layer 23 is preferably formed of a material consisting of silicon and oxygen, or a material consisting of silicon, oxygen, and one or more elements selected from metalloid elements and non-metal elements. The upper layer 23 may contain any metalloid elements in addition to silicon. Among the metalloid elements, one or more elements selected from boron, germanium, antimony, and tellurium are preferably contained because an increase in conductivity of silicon used as a sputtering target is expected.

The upper layer 23 may contain any non-metal elements in addition to oxygen. The non-metal elements in this case include narrow-sense non-metal elements (nitrogen, carbon, oxygen, phosphorus, sulfur, and selenium), halogens, and noble gases. Among the non-metal elements, one or more elements selected from carbon, fluorine, and hydrogen are preferably contained. The upper layer 23 may contain a noble gas, like the lower layer 21.

The upper layer 23 is required to have a stable internal structure hardly changed in optical characteristics under repeated irradiation with the ArF exposure light as compared with the intermediate layer 22 and the lower layer 21. The upper layer 23 is required to have a function of inhibiting intrusion of oxygen in air from a surface of the intermediate layer 22 into the inside thereof. Therefore, the upper layer 23 is preferably greater in oxygen content than the lower layer 21 and the intermediate layer 22. This is because Si—O bonds are higher in structural stability than Si—N bonds. Presence of a large amount of Si—Si bonds or Si which is not bonded with other atoms is not preferable because Si is bonded with oxygen to cause significant change in optical characteristics.

From the above-mentioned reason, the upper layer 23 preferably has an oxygen content of 50 atomic % or more, more preferably 55 atomic % or more, further preferably 60 atomic % or more. The upper layer 23 preferably has an oxygen content of 66 atomic % or less. If the upper layer 23 contains oxygen at a mixing ratio greater than that in SiO₂, it is difficult to form the upper layer 23 into an amorphous or a microcrystalline structure. In addition, surface roughness of the upper layer 23 is seriously degraded. On the other hand, the upper layer 23 preferably has a nitrogen content of 10 atomic % or less, more preferably 5 atomic % or less, further preferably do not positively contain oxygen (not higher than a detection lower limit when composition analysis is carried out by X-ray photoelectron spectroscopy or the like). If the nitrogen content of the upper layer 23 is great, the optical characteristics easily change under the repeated irradiation with the ArF exposure light and the function of protecting the intermediate layer 22 from oxygen in air is decreased.

The upper layer 23 preferably has a silicon content of 33 atomic % or more, more preferably 35 atomic % or more, further preferably 40 atomic % or more. The upper layer 23 is preferably formed of a material consisting of silicon and oxygen. In this case, it is recognized that the material consisting of silicon and oxygen encompasses a material containing a noble gas. In the upper layer 23, the total content of silicon and oxygen is preferably 95 atomic % or more, more preferably 96 atomic % or more, further preferably 98 atomic % or more.

The ratio of the film thickness of the upper layer 23 with respect to the overall film thickness of the phase shift film 2 is preferably 0.10 or less, more preferably 0.08 or less, further preferably 0.06 or less. If the ratio of the film thickness of the upper layer 23 is greater than 0.10, an effect imposed on the optical characteristics of the entire phase shift film 2 is increased and the overall film thickness of the phase shift film 2 is increased. Furthermore, in case where the phase shift film 2 is patterned by dry etching using the fluorine-based gas or in case where a black defect is repaired by EB defect repair, a step at the upper layer 23 imposes a large effect on transfer accuracy of the phase shift mask at the time of exposure transfer.

On the other hand, the ratio of the film thickness of the upper layer 23 with respect to the overall film thickness of the phase shift film 2 is preferably 0.01 or more, more preferably 0.02 or more. If the ratio of the film thickness of the upper layer 23 is smaller than 0.01, it is difficult to exhibit a function of inhibiting intrusion of oxygen in air from the surface of the intermediate layer 22 into the interior thereof.

The lower layer 21 is preferably greater in film thickness than the intermediate layer 22 and the upper layer 23, and the intermediate layer 22 is preferably greater in thickness than the upper layer 23. The phase shift film 2 of the above-mentioned configuration has a high degree of freedom in designing the transmittance and the phase difference.

Most preferably, the lower layer 21, the intermediate layer 22, and the upper layer 23 have the amorphous structure because pattern edge roughness is excellent when the pattern is formed by etching. In case where each of the lower layer 21, the intermediate layer 22, and the upper layer 23 has a composition difficult to form the amorphous structure, a state where the amorphous structure and the microcrystalline structure are mixed is preferable.

The lower layer 21 preferably has a refractive index n of 2.5 or more, more preferably 2.55 or more. The lower layer 21 preferably has an extinction coefficient k of 0.35 or more, more preferably 0.40 or more. On the other hand, the lower layer 21 preferably has a refractive index n of 3.0 or less, more preferably 2.8 or less. The lower layer 21 preferably has an extinction coefficient k of 0.5 or less, more preferably 0.45 or less.

The intermediate layer 22 preferably has a refractive index n of 1.9 or more, more preferably 2.0 or more. The intermediate layer 22 preferably has an extinction coefficient k of 0.1 or more, more preferably 0.15 or more. On the other hand, the intermediate layer 22 preferably has a refractive index n of 2.45 or less, more preferably 2.4 or less. The intermediate layer 22 preferably has an extinction coefficient k of 0.3 or less, more preferably 0.25 or less.

The upper layer 23 preferably has a refractive index of 1.5 or more, more preferably 1.55 or more. The upper layer 23 preferably has an extinction coefficient k of 0.15 or less, more preferably 0.1 or less. On the other hand, the upper layer 23 preferably has a refractive index n of 1.8 or less, more preferably 1.7 or less. The upper layer 23 preferably has an extinction coefficient k of 0 or more.

A refractive index n and an extinction coefficient k of a thin film is not determined only by a composition of the thin film. A film density and a crystalline state of the thin film are also factors affecting the refractive index n and the extinction coefficient k. Therefore, by adjusting various conditions upon forming the thin film by reactive sputtering, the thin film is formed so that the thin film has a desired refractive index n and a desired extinction coefficient k. Film-forming conditions to make the thin film have the refractive index n and the extinction coefficient k in desired ranges are not limited to adjustment of the ratio of a mixture of the noble gas and a reactive gas upon forming the thin film by reactive sputtering. The above-mentioned film-forming conditions include a wide variety of conditions such as a pressure in the film-forming chamber during formation of the thin film by reactive sputtering, an electric power applied to the target, and a positional relationship such as a distance between the target and the transparent substrate. These film-forming conditions are specific to a film-forming apparatus and are appropriately adjusted so that the thin film to be formed has the desired refractive index n and the desired extinction coefficient k.

The lower layer 21, the intermediate layer 22, and the upper layer 23 are formed by sputtering. Any sputtering such as DC sputtering, RF sputtering, and ion beam sputtering may be applicable. In case where a target low in conductivity (silicon target, silicon compound target containing no or a small content of metalloid element, and so on) is used, it is preferable to apply the RF sputtering or the ion beam sputtering. Taking a film-forming rate into consideration, it is more preferable to apply the RF sputtering.

If the phase shift film 2 has large film stress, there arises a problem that, when the phase shift mask is manufactured from the mask blank, displacement of the transfer pattern formed on the phase shift film 2 is increased. The film stress of the phase shift film 2 is preferably 275 MPa or less, more preferably 165 MPa or less, further preferably 110 MPa or less. The phase shift film 2 formed by the above-mentioned sputtering has relatively large film stress. Therefore, the phase shift film 2 after it is formed by sputtering is preferably subjected to heating treatment or light irradiation treatment by a flash lamp or the like so as to reduce the film stress of the phase shift film 2.

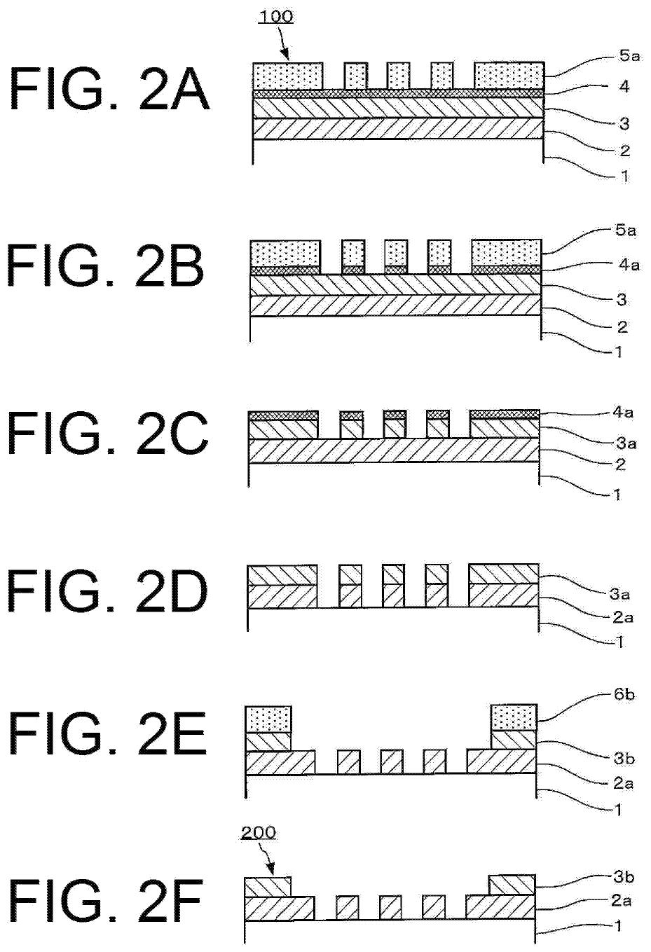

The mask blank 100 preferably has the light shielding film 3 on the phase shift film 2. Generally, in a phase shift mask 200 (see FIG. 2F), an outer peripheral region outside an area where the transfer pattern is to be formed (transfer pattern forming area) is required to secure an optical density (OD) of a predetermined value or more so that, when exposure transfer is carried out onto a resist film on a semiconductor wafer by using an exposure apparatus, the resist film is not affected by exposure light transmitted through the outer peripheral region. The outer peripheral region of the phase shift mask 200 is at least required to have an optical density greater than 2.0.

As described above, the phase shift film 2 has a function of transmitting the exposure light at a predetermined transmittance and the above-mentioned optical density is difficult to be secured only by the phase shift film 2. Therefore, in a stage of manufacturing the mask blank 100, it is desired that the light shielding film 3 is formed as a layer on the phase shift film 2 in order to supplement an insufficient optical density. With the mask blank 100 having the above-mentioned configuration, it is possible to manufacture the phase shift mask 200 with the above-mentioned optical density secured in the outer peripheral region if the light shielding film 3 in an area where the phase shift effect is used (basically, the transfer pattern forming area) is removed in the middle of manufacturing the phase shift mask 200. The mask blank 100 preferably has an optical density of 2.5 or more in the layered structure of the phase shift film 2 and the light shielding film 3, more preferably 2.8 or more. In order to reduce the film thickness of the light shielding film 3, the optical density in the layered structure of the phase shift film 2 and the light shielding film 3 is preferably 4.0 or less.

For the light shielding film 3, both of a single-layer structure and a layered structure of two or more layers are applicable. The light shielding film 3 of the single-layer structure and each layer of the light shielding film 3 having the layered structure of two or more layers may have a configuration that a composition is substantially same in a thickness direction of the film or the layer, or a configuration with composition gradient in the thickness direction of the layer.

For the light shielding film 3, a material having a sufficient etching selectivity for the etching gas used upon forming the pattern on the phase shift film 2 must be applied in case where no other film is interposed between the light shielding film and the phase shift film 2. In this case, the light shielding film 3 is preferably formed of a material containing chromium. The material which forms the light shielding film 3 and which contains chromium may be chromium metal or a material containing chromium and one or more elements selected from oxygen, nitrogen, carbon, boron, and fluorine.

Generally, a chromium-based material is etched by a mixture of a chlorine-based gas and an oxygen gas. However, the chromium metal is not so high in etching rate for such etching gas. Taking into account increasing the etching rate for the etching gas which is the mixture of the chlorine-based gas and the oxygen gas, a material containing chromium and one or more elements selected from oxygen, nitrogen, carbon, boron, and fluorine is preferably used as the material forming the light shielding film 3. The material which forms the light shielding film 3 and which contains chromium may further contain one or more elements selected from molybdenum and tin. By containing one or more elements selected from molybdenum and tin, it is possible to increase the etching rate for the mixture of the chlorine-based gas and the oxygen gas.

On the other hand, in case where another film is interposed between the light shielding film 3 and the phase shift film 2 in the mask blank 100, the above-mentioned another film (etching stopper and etching mask film) is formed of the above-mentioned material containing chromium whereas the light shielding film 3 is formed of the material containing silicon. The material containing chromium is etched by the mixture of the chlorine-based gas and the oxygen gas whereas the resist film formed of an organic material is easily etched by the mixture. The material containing silicon is generally etched by a fluorine-based gas or a chlorine-based gas. Basically, these etching gases do not contain oxygen and, accordingly, an amount of reduction of the resist film of the organic material can be decreased as compared with the case where etching is carried out using the mixture of the chlorine-based gas and the oxygen gas. Therefore, the film thickness of the resist film can be reduced.

The material containing silicon and forming the light shielding film 3 may contain a transition metal or may contain a metal element other than the transition metal. The reason is as follows. In case where the phase shift mask 200 is manufactured from the mask blank 100, a pattern formed by the light shielding film 3 is basically a light shielding zone pattern in the outer peripheral region and is irradiated with the ArF exposure light in a less cumulative amount as compared with a transfer pattern forming region. In addition, the light shielding film 3 rarely remains in a fine pattern and any substantial problem is difficult to occur even if ArF lightfastness is low. When the light shielding film 3 contains a transition metal, a light shielding performance is considerably improved as compared with the case where no transition metal is contained. It is therefore possible to reduce the thickness of the light shielding film 3. The transition metal contained in the light shielding film 3 may be any one metal selected from molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), niobium (Nb), and palladium (Pd) or a compound of these metals.

On the other hand, as the material containing silicon and forming the light shielding film 3, a material consisting of silicon and nitrogen or a material containing one or more elements selected from metalloid elements and non-metal elements in addition to the material consisting of silicon and nitrogen may be applied.

The above-mentioned mask blank 100 comprising the light shielding film 3 formed as a layer on the phase shift film 2 preferably has a structure in which a hard mask film 4 formed of a material having an etching selectivity for the etching gas used in etching the light shielding film 3 is further formed as a layer on the light shielding film 3. Since the light shielding film 3 requires a function of securing a predetermined optical density, there is a limit in reducing the thickness thereof. It is sufficient that the hard mask film 4 has a film thickness allowing the hard mask film to function as an etching mask until completion of dry etching to form a pattern on the light shielding film 3 directly thereunder. Basically, no optical limitation is imposed on the hard mask film. Therefore, the thickness of the hard mask film 4 can be considerably reduced as compared with the thickness of the light shielding film 3. It is sufficient that the resist film of the organic material has a film thickness allowing the resist film to function as an etching mask until completion of dry etching to form a pattern on the hard mask film 4. Therefore, the thickness of the resist film can considerably be reduced than in the past.

In case where the light shielding film 3 is formed of the material containing chromium, the hard mask film 4 is preferably formed of the above-mentioned material containing silicon. The hard mask film 4 in this case tends to be low in adhesion with the resist film of the organic material. Therefore, it is preferable to perform HMDS (Hexamethyldisilazane) treatment on a surface of the hard mask film 4 so as to improve the adhesion of the surface. More preferably, the hard mask film 4 in this case is formed of SiO₂, SiN, SiON, or the like. As a material of the hard mask film 4 in case where the light shielding film 3 is formed of the material containing chromium, a material containing tantalum is applicable in addition to the above-mentioned materials. The material containing tantalum in this case may be tantalum metal or a material containing tantalum and one or more elements selected from nitrogen, oxygen, boron, and carbon. For example, the material may be Ta, TaN, TaON, TaBN, TaBON, TaCN, TaCON, TaBCN, or TaBOCN. On the other hand, when the light shielding film 3 is formed of the material containing silicon, the hard mask film 4 is preferably formed of the above-mentioned material containing chromium.

In the mask blank 100, the resist film of the organic material is preferably formed in contact with the surface of the hard mask film 4 to a film thickness of 100 nm or less. In case of a fine pattern corresponding to the DRAM of hp 32 nm generation, the transfer pattern (phase shift pattern) to be formed on the hard mask film 4 is sometimes provided with SRAF (Sub-Resolution Assist Feature) having a line width of 40 nm. Even in this event, however, a cross-section aspect ratio of a resist pattern can be lowered to 1:2.5. Therefore, it is possible to prevent the resist pattern from being collapsed or detached during development or rinsing of the resist film. More preferably, the resist film has a film thickness of 80 nm or less.

In FIGS. 2A-2F, a process of manufacturing the phase shift mask 200 from the mask blank 100 according to the embodiment of this disclosure is illustrated in schematic sectional views.

The phase shift mask 200 according to this disclosure comprises the transparent substrate 1 and the phase shift film 2 formed thereon and provided with the transfer pattern, and is characterized in that the phase shift film 2 (phase shift pattern 2a) has the structure in which the lower layer 21, the intermediate layer 22, and the upper layer 23 are formed in this order from the transparent substrate 1; that the lower layer 21 is formed of a material consisting of silicon and nitrogen or a material consisting of silicon, nitrogen, and one or more elements selected from metalloid elements and non-metal elements; that the intermediate layer 22 is formed of a material consisting of silicon, nitrogen, and oxygen or a material consisting of silicon, nitrogen, oxygen, and one or more elements selected from metalloid elements and non-metal elements, that the upper layer 23 is formed of a material consisting of silicon and oxygen, or a material consisting of silicon, oxygen, and one or more elements selected from metalloid elements and non-metal elements, that the lower layer 21 is greater in nitrogen content than the intermediate layer 22 and the upper layer 23, that the upper layer 23 is greater in oxygen content than the intermediate layer 22 and the lower layer 21, that a ratio of the film thickness of the intermediate layer 22 with respect to the overall film thickness of the phase shift film 2 is 0.15 or more, and that a ratio of the film thickness of the upper layer 23 with respect to the overall film thickness of the phase shift film 2 is 0.10 or less.

The phase shift mask 200 is similar in technical characteristics to the mask blank 100. The matters regarding the transparent substrate 1, the phase shift film 2, and the light shielding film 3 in the phase shift mask 200 are similar to those described with reference to FIG. 1. The phase shift mask 200 is capable of inhibiting variation in transmittance and phase difference of the phase shift film 2 (phase shift pattern 2a) that is caused under the repeated irradiation with the ArF exposure light. It is also possible to reduce a step produced at a sidewall of the pattern of the phase shift film 2 (phase shift pattern 2a). Furthermore, it is possible to reduce a step produced at the sidewall of the pattern of the phase shift film 2 (phase shift pattern 2a) after EB defect repair when the EB defect repair is performed on the pattern of the phase shift mask 2 (phase shift pattern 2a).

Hereinafter, according to a manufacturing process illustrated in FIGS. 2A-2F, one example of a method for manufacturing the phase shift mask 200 will be described. In this example, the material containing chromium is used as the light shielding film 3 whereas the material containing silicon is used as the hard mask film 4.

At first, the resist film was formed by spin coating in contact with the hard mask film 4 in the mask blank 100. Next, on the resist film, a first pattern as a transfer pattern (phase shift pattern) to be formed on the phase shift film 2 was written by exposure. Furthermore, a predetermined process such as development was carried out to form a first resist pattern 5a having the phase shift pattern (see FIG. 2A). Subsequently, with the first resist pattern 5a used as a mask, dry etching using a fluorine-based gas was carried out to form a first pattern (hard mask pattern 4a) on the hard mask film 4 (see FIG. 2B).

Next, after removing the first resist pattern 5a, dry etching using a mixture of a chlorine-based gas and an oxygen gas was carried out with the hard mask pattern 4a used as a mask, to form a first pattern (light shielding pattern 3a) on the light shielding film 3 (see FIG. 2C). Subsequently, with the light shielding pattern 3a used as a mask, dry etching using a fluorine-based gas was carried out to form the first pattern (phase shift pattern 2a) on the phase shift film 2 and simultaneously remove the hard mask pattern 4a (see FIG. 2D).

Next, the resist film was formed on the mask blank 100 by spin coating. Next, a second pattern as a pattern to be formed on the light shielding film 3 (light shielding pattern) was written by exposure on the resist film. Furthermore, a predetermined process such as development was carried out to form a second resist pattern 6b having the light shielding pattern. Subsequently, with the second resist pattern 6b used as a mask, dry etching using a mixture of a chlorine-based gas and an oxygen gas was carried out to form the second pattern (light shielding pattern 3b) on the light shielding film 3 (see FIG. 2E). Furthermore, the second resist pattern 6b was removed. Through a predetermined process such as cleaning, the phase shift mask 200 was obtained (see FIG. 2F).

The chlorine-based gas used in the dry etching mentioned above is not particularly limited as far as Cl is contained. For example, the chlorine-based gas may be Cl₂, SiCl₂, CHCl₃, CH₂Cl₂, CCl₄, BCI₃, and so on. The fluorine-based gas used in the dry etching mentioned above is not particularly limited as far as F is contained. For example, the fluorine-based gas may be CHF₃, CF₄, C₂F₆, C₄F₈, SF₆, and so on. In particular, since the fluorine-based gas free from C is relatively low in etching rate for the transparent substrate 1 of a glass material, a damage against the transparent substrate 1 can further be reduced.

Furthermore, a method for manufacturing a semiconductor device according to this disclosure is characterized in that the pattern is exposure-transferred to the resist film on the semiconductor substrate using the phase shift mask 200 manufactured using the mask blank 100 mentioned above. The mask blank 100 according to this disclosure and the phase shift mask 200 manufactured using the mask blank 100 have the effect as mentioned above. Therefore, when the phase shift mask 200 is set on the mask stage of the exposure apparatus with the ArF excimer laser used as the exposure light and the phase shift pattern 2a is exposure-transferred to the resist film on the semiconductor substrate, it is possible to transfer the pattern onto the resist film on the semiconductor substrate with an accuracy sufficiently satisfying the design specification.

On the other hand, as another embodiment related to this disclosure, a mask blank having the following configuration is given. Specifically, the mask blank according to another embodiment comprises a transparent substrate and a phase shift film formed thereon and is characterized in that the phase shift film has a structure in which a lower layer and an upper layer are formed in this order from the transparent substrate, that the lower layer is formed of a material consisting of silicon, nitrogen, and oxygen or a material consisting of silicon, nitrogen, oxygen and one or more elements selected from metalloid elements and non-metal elements, that the upper layer is formed of a material consisting of silicon and oxygen or a material consisting of silicon, oxygen, and one or more elements selected from metalloid elements and non-metal elements, that the lower layer is greater in nitrogen content that the upper layer, that the upper layer is greater in oxygen content than the lower layer, that the lower layer has a nitrogen content of 30 atomic % or more and an oxygen content of 10 atomic % or more, and that a ratio of the film thickness of the upper layer with respect to the overall film thickness of the phase shift film is 0.10 or less.

The mask blank of the above-mentioned another embodiment has the configuration particularly suitable in case of the phase shift film having a relatively high transmittance for the ArF exposure light, for example, having a transmittance of 20% or more. The lower layer of the phase shift film in this another embodiment is similar in configuration to the intermediate layer of the above-mentioned phase shift film according to the embodiment of this disclosure. However, in this another embodiment, a ratio of the film thickness of the lower layer with respect to the overall thickness of the phase shift film is preferably 0.90 or more, more preferably 0.95 or more. Furthermore, in this another embodiment, the ratio of the film thickness of the lower layer is preferably 0.99 or less, more preferably 0.97 or less. Other matters related to the mask blank of this another embodiment are similar to those of the above-mentioned mask blank according to the embodiment of this disclosure.

In the mask blank according to this another embodiment, the lower layer of the phase shift film is formed of a silicon oxynitride based material and, as compared with the silicon nitride based material, is hardly changed in optical characteristics under the repeated irradiation with the ArF exposure light. The lower layer of the silicon oxynitride based material has an intermediate characteristic that the etching rate for dry etching by the fluorine-based gas is slower than that of a thin film of the silicon nitride based material and faster than that of the upper layer of the silicon oxide based material. Furthermore, the lower layer of the silicon oxynitride based material has an intermediate characteristic that a repair rate at the time of EB defect repair is slower than that of the thin film of the silicon nitride based material and faster than that of the upper layer of the silicon oxide based material. By the mask blank having the above-mentioned phase shift film, it is possible to inhibit variation in transmittance and phase difference of the phase shift film caused under the repeated irradiation with the ArF exposure light. Furthermore, it is possible to reduce a step produced at a sidewall of a pattern of the phase shift film when the phase shift film is dry etched by the fluorine-based gas to form the pattern. Moreover, when EB defect repair is performed on a pattern of a phase shift film of a phase shift mask manufactured from the mask blank, it is possible to reduce a step produced at a sidewall of the pattern of the phase shift film after the EB defect repair.

Furthermore, a phase shift mask according to another embodiment, similar in characteristics to the mask blank of another embodiment mentioned above, may be given. Specifically, the phase shift mask according to another embodiment comprises a transparent substrate and a phase shift film formed thereon and provided with a transfer pattern and is characterized in that the phase shift film has a structure in which a lower layer and an upper layer are formed in this order from the transparent substrate, that the lower layer is formed of a material consisting of silicon, nitrogen, and oxygen or a material consisting of silicon, nitrogen, oxygen, and one or more elements selected from metalloid elements and non-metal elements, that the upper layer is formed of a material consisting of silicon and oxygen or a material consisting of silicon, oxygen, and one or more elements selected from metalloid elements and non-metal elements, that the lower layer is greater in nitrogen content than the upper layer, that the upper layer is greater in oxygen content than the lower layer, that the lower layer has a nitrogen content of 30 atomic % or more and an oxygen content of 10 atomic % or more, and that a ratio of the film thickness of the upper layer with respect to the overall thickness of the phase shift film is 0.10 or less.

Like in case of the mask blank according to another embodiment mentioned above, the phase shift mask according to another embodiment is capable of inhibiting variation in transmittance and phase difference of the phase shift film caused under the repeated irradiation with the ArF exposure light. When the phase shift film is dry etched by the fluorine-based gas to form a pattern, it is possible to reduce a step produced at a sidewall of the pattern of the phase shift film. Furthermore, when EB defect repair is performed on a pattern of a phase shift film of a phase shift mask of another embodiment manufactured from the mask blank of this another embodiment, it is possible to reduce a step formed at a sidewall of the pattern of the phase shift film after the EB defect repair. When the phase shift mask of this another embodiment is set on the mask stage of the exposure apparatus with the ArF excimer laser used as the exposure light and the phase shift pattern is exposure-transferred onto the resist film on the semiconductor substrate, it is possible to transfer the pattern onto the resist film on the semiconductor substrate with an accuracy sufficiently satisfying the design specification.

### EXAMPLES

Hereinafter, the embodiments of this disclosure will more specifically be described with reference to several examples.

### Example 1

### Manufacture of Mask Blank

A transparent substrate 1 made of synthetic quartz glass with a main surface having a size of about 152 mm×about 152 mm and a thickness of about 6.25 mm was prepared. In the transparent substrate 1, an end face and the main surface were polished to a predetermined surface roughness. Thereafter, the transparent substrate were subjected to predetermined cleaning and predetermined drying.

Next, on the transparent substrate 1, a phase shift film 2 having a three-layer structure comprising a lower layer 21, an intermediate layer 22, and an upper layer 23 was formed through the following steps. At first, on the transparent substrate 1, the lower layer 21 consisting of silicon and nitrogen (SiN layer of Si:N=49.5 atomic %:50.5 atomic %) was formed to a thickness of 51 nm. The lower layer 21 is formed by placing the transparent substrate 1 in a single-wafer RF sputtering apparatus and by carrying out reactive sputtering by an RF power supply (RF sputtering), using a silicon (Si) target and a mixture of krypton (Kr), helium (He), and nitrogen (N₂) as a sputtering gas.

Next, on the lower layer 21, the intermediate layer 22 consisting of silicon, nitrogen, and oxygen (SiON layer of Si:O:N=41.9 atomic %:24.5 atomic %:33.6 atomic %) was formed to a thickness of 11.6 nm. The intermediate layer 22 is formed by placing the transparent substrate 1 with the lower layer 21 formed thereon in the single-wafer RF sputtering apparatus and by carrying out reactive sputtering by the RF power supply (RF sputtering), using a silicon (Si) target and a mixture of krypton (Kr), helium (He), oxygen (O₂), and nitrogen (N₂) as a sputtering gas.

Subsequently, on the intermediate layer 22, the upper layer 23 consisting of silicon and oxygen (SiO layer of Si:O=35.0 atomic %:65.0 atomic %) was formed to a thickness of 4.1 nm. The upper layer 23 was formed by placing the transparent substrate 1 with the lower layer 21 and the intermediate layer 22 formed thereon in the single-wafer RF sputtering apparatus and by carrying out reactive sputtering by the RF power supply (RF sputtering), using a silicon dioxide (SiO₂) target and an argon (Ar) gas as a sputtering gas. The compositions of the lower layer 21, the intermediate layer 22, and the upper layer 23 were obtained as a result of measurement by X-ray photoelectron spectroscopy (XPS). Hereinafter, this also applies to other films and layers.

Next, the transparent substrate 1 with the phase shift film 2 formed thereon is subjected to heat treatment for reducing film stress of the phase shift film 2. For the phase shift film 2 after the heat treatment, a transmittance and a phase difference at a wavelength (about 193 nm) of the ArF excimer laser light were measured by a phase shift measurement apparatus (MPM-193 manufactured by Lasertec Corporation). As a result, the phase shift film 2 had a transmittance of 19.17% and a phase difference of 180.50 degrees (deg). Furthermore, optical characteristics of the phase shift film 2 were measured using a spectroscopic ellipsometer (M-2000D manufactured by J. A. Woollam Co.). As a result, the lower layer 21 had a refractive index n of 2.63 and an extinction coefficient k of 0.43. The intermediate layer 22 had a refractive index n of 2.24 and an extinction coefficient k of 0.13. The upper layer 23 had a refractive index n of 1.56 and an extinction coefficient k of 0.00.

Next, on a main surface of another transparent substrate, another phase shift film was formed under the same film-forming conditions as the above-mentioned phase shift film 2 of Example 1. Furthermore, heat treatment was carried out under the same conditions. This another transparent substrate and this another phase shift film after the heat treatment were subjected to intermittent irradiation with the ArF excimer laser light in a cumulative irradiation amount of 20 kJ/cm². For the phase shift film after the intermittent irradiation, a transmittance and a phase difference at the wavelength (about 193 nm) of the ArF excimer laser light were measured by the same phase shift measurement apparatus. As a result, the phase shift film had a transmittance of 20.07% and a phase difference of 179.85 degrees (deg). Before and after the intermittent irradiation, a variation in transmittance of the phase shift film was +0.9% and a variation in phase difference was −0.65 degrees (deg). Thus, the variation in each of transmittance and phase difference was sufficiently inhibited.

Next, in contact with the phase shift film 2, the light shielding film 3 of CrOC was formed to a thickness of 56 nm. The light shielding film 3 was formed by placing, in the single-wafer DC sputtering apparatus, the transparent substrate 1 provided with the phase shift film 2 after the heat treatment and by carrying out reactive sputtering (DC sputtering) by using a chromium (Cr) target and a mixture of argon (Ar), carbon dioxide (CO₂), and helium (He) (flow rate ratio Ar:CO₂:He=18:33:28, pressure=0.15 Pa) as a sputtering gas with an electric power of 1.8 kW from a DC power supply.

Furthermore, the hard mask film 4 consisting of silicon and oxygen was formed on the light shielding film 3 to a thickness of 5 nm. The hard mask film 4 was formed by placing the transparent substrate 1 with the phase shift film 2 and the light shielding film 3 formed as layers in the single-wafer RF sputtering apparatus and by carrying out RF sputtering using a silicon dioxide (SiO₂) target and an argon (Ar) gas (pressure=0.03 Pa) as a sputtering gas with an electric power of 1.5 kW from the DC power supply. By the above-mentioned steps, the mask blank 100 having a structure in which the phase shift film 2, the light shielding film 3, and the hard mask film 4 are formed as layers on the transparent substrate 1 was manufactured.

### Manufacture of Phase Shift Mask

Next, using the mask blank 100 of Example 1, the phase shift mask 200 of Example 1 was manufactured through the following steps. At first, a surface of the hard mask film 4 was subjected to HMDS treatment. Subsequently, a resist film of a chemically amplified resist for electron beam writing was formed by spin coating in contact with the surface of the hard mask film 4 to a film thickness of 80 nm. Then, on the resist film, a first pattern as a phase shift pattern to be formed on the phase shift film 2 was formed by electron beam writing. Furthermore, predetermined development and predetermined cleaning were carried out to form a first resist pattern 5a having the first pattern (see FIG. 2A). At this time, the first resist pattern 5a formed by electron beam writing was given a program defect, in addition to the transfer pattern to be formed, so that a black defect is formed on the phase shift film 2.

Next, using the first resist pattern 5a as a mask, dry etching using a CF₄ gas was carried out to form the first pattern (hard mask pattern 4a) on the hard mask film 4 (see FIG. 2B).

Then, the first resist pattern 5a was removed. Subsequently, using the hard mask pattern 4a as a mask and a mixture of chlorine and oxygen (gas flow rate ratio Cl₂:O₂=4:1), dry etching was carried out to form the first pattern (light shielding pattern 3a) on the light shielding film 3 (see FIG. 2C).

Next, with the light shielding pattern 3a used as a mask and using a fluorine-based gas (mixture of SF₆ and He), dry etching was carried out to form the first pattern (phase shift pattern 2a) on the phase shift film 2 and to remove the hard mask pattern 4a simultaneously (see FIG. 2D).

Next, on the light shielding pattern 3a, a resist film of a chemically amplified resist for electron beam writing was formed by spin coating to a film thickness of 150 nm. Then, on the resist film, a second pattern as a pattern (light shielding pattern) to be formed on the light shielding film 3 was written by exposure. Furthermore, a predetermined process such as development was carried out to form a second resist pattern 6b having the light shielding pattern. Subsequently, with the second resist pattern 6b used as a mask and using a mixture of chlorine and oxygen (gas flow rate ratio Cl₂:O₂=4:1), dry etching was carried out to form the second pattern (light shielding pattern 3b) on the light shielding film 3 (see FIG. 2E). Furthermore, the second resist pattern 6b was removed and, through cleaning, the phase shift mask 200 was obtained (see FIG. 2F).

For the phase shift mask 200 of Example 1 thus manufactured was inspected for a mask pattern by a mask inspection apparatus. As a result, presence of the black defect was confirmed in the phase shift pattern 2a at a position where the program defect was placed. The black defect was removed by EB defect repair

On the other hand, the phase shift mask 200 of Example 1 was additionally manufactured through the similar steps and the black defect (program defect) was removed therefrom by EB defect repair. The phase shift pattern 2a of the phase shift mask 200 after removal of the black defect was observed by a cross-section TEM (Transmission Electron Microscope). As a result, in the phase shift pattern 2a at a position where the black defect was removed, a step in a sidewall shape was considerably reduced owing to a layered structure of the lower layer 21, the intermediate 22, and the upper layer 23. Furthermore, the phase shift pattern 2a except the position where the black defect was removed was observed by the cross-section TEM. As a result, in the phase shift pattern 2a, a step in the sidewall shape was considerably reduced owing to the layered structure of the lower layer 21, the intermediate layer 22, and the upper layer 23.

The phase shift pattern 2a of the halftone phase shift mask 200 in Example 1 thus manufactured was subjected to intermittent irradiation with the ArF excimer laser light in a cumulative irradiation amount of 20 kJ/cm². Next, by using AIMS193 (manufactured by Carl Zeiss AG), the phase shift mask 200 of Example 1 after the cumulative irradiation with the ArF excimer laser light was subjected to simulation of a transfer image when exposure transfer onto the resist film on a semiconductor substrate was carried out with exposure light having a wavelength of 193 nm. Examining an exposure transfer image in the simulation, the design specification was fully satisfied. From this result, it is said that a circuit pattern can finally be formed on the semiconductor substrate with high accuracy when the phase shift mask 200 in Example 1 after the cumulative irradiation with the ArF excimer laser light is set on the mask stage of the exposure apparatus and exposure transfer is carried out onto the resist film on the semiconductor substrate.

### Example 2

### Manufacture of Mask Blank

The mask blank 100 in Example 2 was manufactured through the steps similar to Example 1 except the phase shift film 2. Specifically, through the steps similar to Example 1, the lower layer 21 consisting of silicon and nitrogen (SiN layer of Si:N=48.5 atomic %:51.5 atomic %) was formed on the transparent substrate 1 to a thickness of 40.6 nm. Next, on the lower layer 21, the intermediate layer 22 consisting of silicon, nitrogen, and oxygen (SiON layer of Si:O:N=41.9 atomic %, 24.5 atomic %, 33.6 atomic %) was formed to a thickness of 24.6 nm. Next, on the intermediate layer 22, the upper layer 23 consisting of silicon and oxygen (SiO layer of Si:O=35.0 atomic %:65.0 atomic %) was formed to a thickness of 4.3 nm.

Under the similar processing conditions to Example 1, the phase shift film 2 in Example 2 was subjected to heat treatment. By using the same phase shift measuring apparatus as in Example 1, a transmittance and a phase difference of the phase shift film 2 for the light having a wavelength of 193 nm were measured. As a result, the phase shift film 2 had a transmittance of 28.07% and a phase difference of 178.86 degrees (deg). By using the same spectroscopic ellipsometer as in Example 1, optical characteristics of the phase shift film 2 in Example 2 were measured. As a result, the lower layer 21 had a refractive index n of 2.58 and an extinction coefficient k of 0.35. The intermediate layer 22 had a refractive index n of 2.24 and an extinction coefficient k of 0.13. The upper layer 23 had a refractive index n of 1.56 and an extinction coefficient k of 0.00.

In the manner similar to Example 1, on a main surface of another transparent substrate, another phase shift film was formed under the same film-forming conditions as the phase shift film 2 of Example 1. Furthermore, heat treatment was carried out under the same conditions. This another transparent substrate and this another different phase shift film after the heat treatment were subjected to intermittent irradiation with the ArF excimer laser light in a cumulative irradiation amount of 20 kJ/cm². For the phase shift film after the intermittent irradiation, a transmittance and a phase difference at the wavelength (about 193 nm) of the ArF excimer laser light were measured by the same phase shift measurement apparatus. As a result, the phase shift film had a transmittance of 28.59% and a phase difference of 177.93 degrees (deg). Before and after the intermittent irradiation, a variation in transmittance of the phase shift film was +0.52% and a variation in phase difference was −0.93 degrees (deg). Thus, the variation in each of transmittance and phase difference was sufficiently inhibited.

By the above-mentioned steps, the mask blank 100 in Example 2 having a structure in which the phase shift film 2 comprising the lower layer 21, the intermediate layer 22, and the upper layer 23, the light shielding film 3, and the hard mask film 4 are formed as layers on the transparent substrate 1 was manufactured.

### Manufacture of Phase Shift Mask

Next, using the mask blank 100 of Example 2, the phase shift mask 200 of Example 2 was manufactured through the steps similar to Example 1. For the phase shift mask 200 of Example 2 thus manufactured was inspected for a mask pattern by the mask inspection apparatus. As a result, presence of a black defect was confirmed in the phase shift pattern 2a at a position where a program defect was placed. The black defect was removed by EB defect repair.

On the other hand, the phase shift mask 200 of Example 2 was additionally manufactured through the steps similar to Example 1 and the black defect (program defect) was removed therefrom by EB defect repair. The phase shift pattern 2a of the phase shift mask 200 after removal of the black defect was observed by a cross-section TEM (Transmission Electron Microscope). As a result, in the phase shift pattern 2a at a position where the black defect was removed, a step in a sidewall shape was considerably reduced owing to a layered structure of the lower layer 21, the intermediate 22, and the upper layer 23. Furthermore, the phase shift pattern 2a except the position where the black defect was removed was observed by the cross-section TEM. As a result, in the phase shift pattern 2a, a step in the sidewall shape was considerably reduced owing to the layered structure of the lower layer 21, the intermediate layer 22, and the upper layer 23.

The phase shift pattern 2a of the halftone phase shift mask 200 in Example 2 thus manufactured was subjected to intermittent irradiation with the ArF excimer laser light in a cumulative irradiation amount of 20 kJ/cm². Next, by using AIMS193 (manufactured by Carl Zeiss AG), the phase shift mask 200 of Example 2 after the cumulative irradiation with the ArF excimer laser light was subjected to simulation of a transfer image when exposure transfer onto the resist film on a semiconductor substrate was carried out with exposure light having a wavelength of 193 nm. Examining an exposure transfer image in the simulation, the design specification was fully satisfied. From this result, it is said that a circuit pattern can finally be formed on the semiconductor substrate with high accuracy when the phase shift mask 200 in Example 2 after the cumulative irradiation with the ArF excimer laser light is set on the mask stage of the exposure apparatus and exposure transfer is carried out onto the resist film on the semiconductor substrate.

### Comparative Example 1

### Manufacture of Mask Blank

A mask blank of Comparative Example 1 was manufactured through the steps similar to Example 1 except a phase shift film. Specifically, on a transparent substrate, the phase shift film having a single-layer structure consisting of silicon and nitrogen (SiN film of Si:N=48.5 atomic %:51.5 atomic %) was formed to a thickness of 61.3 nm. The phase shift film was formed by placing the transparent substrate in a single-wafer RF sputtering apparatus and by carrying out reactive sputtering (RF sputtering) by an RF power supply, using a silicon (Si) target and a mixture of krypton (Kr), helium (He), and nitrogen (N₂) as a sputtering gas.

Under the similar processing conditions to Example 1, the phase shift film in Comparative Example 1 was subjected to heat treatment. By using the same phase shift measuring apparatus as in Example 1, a transmittance and a phase difference of the phase shift film for the light having a wavelength of 193 nm were measured. As a result, the phase shift film had a transmittance of 18.56% and a phase difference of 177.28 degrees (deg). By using the same spectroscopic ellipsometer as in Example 1, optical characteristics of the phase shift film in Comparative Example 1 were measured. As a result, the refractive index n was 2.60 and the extinction coefficient k was 0.36.

In the manner similar to Example 1, on a main surface of another transparent substrate, another phase shift film was formed under the same film-forming conditions as the phase shift film of Comparative Example 1. Furthermore, heat treatment was carried out under the same conditions. This another transparent substrate and this another phase shift film after the heat treatment were subjected to intermittent irradiation with the ArF excimer laser light in a cumulative irradiation amount of 20 kJ/cm². For the phase shift film after the intermittent irradiation, a transmittance and a phase difference at the wavelength (about 193 nm) of the ArF excimer laser light were measured by the same phase shift measurement apparatus. As a result, the phase shift film had a transmittance of 20.05% and a phase difference of 175.04 degrees (deg). Before and after the intermittent irradiation, a variation in transmittance of the phase shift film was +1.49% and a variation in phase difference was −2.24 degrees (deg). Thus, the variation in each of transmittance and phase difference could not sufficiently be inhibited.

By the above-mentioned steps, the mask blank in Comparative Example 1 having a structure in which the phase shift film of a single-layer structure, the light shielding film, and the hard mask film are formed as layers on the transparent substrate was manufactured.

### Manufacture of Phase Shift Mask

Next, using the mask blank of Comparative Example 1, a phase shift mask of Comparative Example 1 was manufactured through the steps similar to Example 1. For the phase shift mask of Comparative Example 1 thus manufactured was inspected for a mask pattern by the mask inspection apparatus. As a result, presence of a black defect was confirmed in the phase shift pattern at a position where a program defect was placed. The black defect was removed by EB defect repair.

On the other hand, the phase shift mask of Comparative Example 1 was additionally manufactured through the steps similar to Example 1 and the black defect (program defect) was removed therefrom by EB defect repair. The phase shift pattern of the phase shift mask after removal of the black defect was observed by a cross-section TEM (Transmission Electron Microscope). As a result, in the phase shift pattern at a position where the black defect was removed, a sidewall shape was excellent. Furthermore, the phase shift pattern except the position where the black defect was removed was observed by the cross-section TEM (Transmission Electron Microwave). As a result, the phase shift pattern had an excellent sidewall shape.

The phase shift pattern of the halftone phase shift mask in Comparative Example 1 thus manufactured was subjected to intermittent irradiation with the ArF excimer laser light in a cumulative irradiation amount of 20 kJ/cm². Next, by using AIMS193 (manufactured by Carl Zeiss AG), the phase shift mask of Comparative Example 1 after the cumulative irradiation with the ArF excimer laser light was subjected to simulation of a transfer image when exposure transfer onto the resist film on a semiconductor substrate was carried out with exposure light having a wavelength of 193 nm. Examining an exposure transfer image in the simulation, the design specification could not be satisfied at a part of a fine pattern. From this result, it is said that a circuit pattern is difficult to be formed on the semiconductor substrate with high accuracy when the phase shift mask in Comparative Example 1 after the cumulative irradiation with the ArF excimer laser light is set on the mask stage of the exposure apparatus and exposure transfer is carried out onto the resist film on the semiconductor substrate.

### Comparative Example 2

### Manufacture of Mask Blank

A mask blank of Comparative Example 2 was manufactured through the steps similar to Example 1 except a phase shift film. Specifically, on a transparent substrate, a lower layer of the phase shift film, consisting of silicon and nitrogen (SiN layer of Si:N=48.5 atomic %:51.5 atomic %), was formed to a thickness of 59.5 nm. The lower layer was formed by placing the transparent substrate in a single-wafer RF sputtering apparatus and by carrying out reactive sputtering (RF sputtering) by an RF power supply, using a silicon (Si) target and a mixture of krypton (Kr), helium (He), and nitrogen (N₂) as a sputtering gas. Subsequently, on the lower layer, an upper layer of the phase shift film, consisting of silicon and oxygen (SiO layer of Si:O=35.0 atomic %:65.0 atomic %), was formed to a thickness of 6.5 nm. The upper layer was formed by placing the transparent substrate provided with the lower layer in the single-wafer RF sputtering apparatus and by carrying out reactive sputtering (RF sputtering) by an RF power supply, using a silicon dioxide (SiO₂) target and an argon (Ar) gas as a sputtering gas.

Under the similar processing conditions to Example 1, the phase shift film in Comparative Example 2 was subjected to heat treatment. Next, by using the same phase shift measuring apparatus as in Example 1, a transmittance and a phase difference of the phase shift film for the light having a wavelength of 193 nm were measured. As a result, the phase shift film had a transmittance of 20.34% and a phase difference of 177.47 degrees (deg). Subsequently, by using the same spectroscopic ellipsometer as in Example 1, optical characteristics of the phase shift film in Comparative Example 2 were measured. As a result, the lower layer had a refractive index n of 2.60 and an extinction coefficient k of 0.36 whereas the upper layer had a refractive index n of 1.56 and an extinction coefficient k of 0.00.

In the manner similar to Example 1, on a main surface of another transparent substrate, another phase shift film was formed under the same film-forming conditions as the phase shift film of Comparative Example 2. Furthermore, heat treatment was carried out under the same conditions. This another transparent substrate and this another phase shift film after the heat treatment were subjected to intermittent irradiation with the ArF excimer laser light in a cumulative irradiation amount of 20 kJ/cm². For the phase shift film after the intermittent irradiation, a transmittance and a phase difference at the wavelength (about 193 nm) of the ArF excimer laser light were measured by the same phase shift measurement apparatus. As a result, the phase shift film had a transmittance of 21.59% and a phase difference of 176.70 degrees (deg). Before and after the intermittent irradiation, a variation in transmittance of the phase shift film was +1.25% and a variation in phase difference was −0.77 degrees (deg). Thus, the variation in transmittance could not sufficiently be inhibited.

By the above-mentioned steps, the mask blank in Comparative Example 2 having a structure in which the phase shift film comprising the lower layer and the upper layer, the light shielding film, and the hard mask film are formed as layers on the transparent substrate was manufactured.

### Manufacture of Phase Shift Mask

Next, using the mask blank of Comparative Example 2, a phase shift mask of Comparative Example 2 was manufactured through the steps similar to Example 1. For the phase shift mask of Comparative Example 2 thus manufactured was inspected for a mask pattern by the mask inspection apparatus. As a result, presence of a black defect was confirmed in the phase shift pattern at a position where a program defect was placed. The black defect was removed by EB defect repair.

On the other hand, the phase shift mask of Comparative Example 2 was additionally manufactured through the steps similar to Example 1 and the black defect (program defect) was removed therefrom by EB defect repair. The phase shift pattern of the phase shift mask after removal of the black defect was observed by a cross-section TEM (Transmission Electron Microscope). As a result, in the phase shift pattern at a position where the black defect was removed, a step in a sidewall shape was large and an excellent sidewall shape was not obtained owing to the layered structure of the lower layer of SiN and the upper layer of SiO. Furthermore, the phase shift pattern except the position where the black defect was observed by the cross-section TEM. As a result, in the phase shift pattern, a step in a sidewall shape was large and an excellent sidewall shape was not obtained owing to the layered structure of the lower layer of SiN and the upper layer of SiO.

The phase shift pattern of the halftone phase shift mask in Comparative Example 2 thus manufactured was subjected to intermittent irradiation with the ArF excimer laser light in a cumulative irradiation amount of 20 kJ/cm². Next, by using AIMS193 (manufactured by Carl Zeiss AG), the phase shift mask of Comparative Example 2 after the cumulative irradiation with the ArF excimer laser light was subjected to simulation of a transfer image when exposure transfer onto the resist film on a semiconductor substrate was carried out with exposure light having a wavelength of 193 nm. Examining an exposure transfer image in the simulation, the design specification could not be satisfied at a part of a fine pattern. From this result, it is said that a circuit pattern is difficult to be formed on the semiconductor substrate with high accuracy when the phase shift mask in Comparative Example 2 after the cumulative irradiation with the ArF excimer laser light is set on the mask stage of the exposure apparatus and exposure transfer is carried out onto the resist film on the semiconductor substrate.

This application is based upon and claims the benefit of priority from Japanese Patent Application No. 2018-058004, filed on Mar. 26, 2018, the disclosure of which is incorporated herein in its entirety by reference.

### EXPLANATION OF REFERENCE NUMERALS

1 transparent substrate
2 phase shift film
2a phase shift pattern
3 light shielding film
3a, 3b light shielding pattern
4 hard mask film
4a hard mask pattern
5a first resist pattern
6b second resist pattern
100 mask blank
200 phase shift mask

Listing of claims:

1. A mask blank comprising:
a transparent substrate; and
a phase shift film formed on the transparent substrate to have a lower layer, an intermediate layer, and an upper layer,
wherein the lower layer of the phase shift film is closer to the transparent substrate than the intermediate layer is, and wherein the upper layer of the phase shift film is farther from the transparent substrate than the intermediate layer is, and
wherein the lower layer contains silicon and nitrogen, and
wherein the intermediate layer contains silicon, nitrogen, and oxygen, and
wherein the upper layer contains silicon and oxygen, and
wherein a nitrogen content of the lower layer is greater than a nitrogen content of the intermediate layer and is greater than a nitrogen content of the upper layer, and
wherein an oxygen content of the upper layer is greater than an oxygen content of the intermediate layer and is greater than an oxygen content of the lower layer, and
wherein a ratio of a film thickness of the intermediate layer to an overall film thickness of the phase shift film is at least 0.15, and
wherein a ratio of a film thickness of the upper layer to the overall film thickness of the phase shift film is not more than 0.10.

2. The mask blank according to claim 1, wherein a ratio of a film thickness of the lower layer to the overall film thickness of the phase shift film is not more than 0.80.

3. The mask blank according to claim 1, wherein the intermediate layer is greater in nitrogen content than the upper layer and greater in oxygen content than the lower layer.

4. The mask blank according to claim 1, wherein the intermediate layer has a nitrogen content of 30 atomic % or more and an oxygen content of 10 atomic % or more.

5. The mask blank according to claim 1, wherein the lower layer has a nitrogen content of 50 atomic % or more.

6. The mask blank according to claim 1, wherein the upper layer has an oxygen content of 50 atomic % or more.

7. The mask blank according to claim 1, wherein a film thickness of the lower layer is greater than the film thickness of the intermediate layer, which is greater than the film thickness of the upper layer.

8. The mask blank according to claim 1, wherein a transmittance of the phase shift film with respect to exposure light of an ArF excimer laser is 2% or more, and
the phase shift film is configured to transmit the exposure light so that transmitted light has a phase difference of 150 degrees or more and 200 degrees or less with respect to the exposure light transmitted through air for a same distance as a thickness of the phase shift film.

9. The mask blank according to claim 1, comprising a light shielding film formed on the phase shift film.

10. A phase shift mask comprising:
a transparent substrate; and
a phase shift film formed on the transparent substrate and having a transparent pattern,
wherein the phase shift film has a lower layer, an intermediate layer, and an upper layer, and
wherein the lower layer of the phase shift film is closer to the transparent substrate than the intermediate layer is, and wherein the upper layer of the phase shift film is farther from the transparent substrate than the intermediate layer is, and
wherein the lower layer contains silicon and nitrogen, and
wherein the intermediate layer contains silicon, nitrogen, and oxygen, and
wherein the upper layer contains silicon and oxygen, and
wherein a nitrogen content of the lower layer is greater than a nitrogen content of the intermediate layer and is greater than a nitrogen content of the upper layer, and
wherein an oxygen content of the upper layer is greater than an oxygen content of the intermediate layer and is greater than an oxygen content of the lower layer, and
wherein a ratio of a film thickness of the intermediate layer to an overall film thickness of the phase shift film is at least 0.15, and
wherein a ratio of a film thickness of the upper layer to the overall film thickness of the phase shift film is not more than 0.10.

11. The phase shift mask according to claim 10, wherein a ratio of a film thickness of the lower layer to the overall film thickness of the phase shift film is not more than 0.80.

12. The phase shift mask according to claim 10, wherein the intermediate layer is greater in nitrogen content than the upper layer and greater in oxygen content than the lower layer.

13. The phase shift mask according to claim 10, wherein the intermediate layer has a nitrogen content of 30 atomic % or more and an oxygen content of 10 atomic % or more.

14. The phase shift mask according to claim 10, wherein the lower layer has a nitrogen content of 50 atomic % or more.

15. The phase shift mask according to claim 10, wherein the upper layer has an oxygen content of 50 atomic % or more.

16. The phase shift mask according to claim 10, wherein a film thickness of the lower layer is greater than the film thickness of the intermediate layer, which is greater than the film thickness of the upper layer.

17. The phase shift mask according to claim 10, wherein a transmittance of the phase shift film with respect to exposure light of an ArF excimer laser is 2% or more, and
the phase shift film is configured to transmit the exposure light so that transmitted light has a phase difference of 150 degrees or more and 200 degrees or less with respect to the exposure light transmitted through air for a same distance as a thickness of the phase shift film.

18. The phase shift mask according to claim 10, further comprising a light shielding film formed on the phase shift film and having a light shielding pattern.

19. A method for manufacturing a semiconductor device, comprising using the phase shift mask according to claim 10 to carry out exposure transfer of a transfer pattern to a resist film on a semiconductor substrate.
